(19) United States
(12) Patent Application Publication
(10) Pub. No.: US 2026/0247721 A1
(43) Pub. Date: Aug. 20, 2026

(54) ELECTROSTATIC DISCHARGE STRUCTURE

(71) Applicant: Vanguard International Semiconductor Corporation, Hsinchu (TW)

(72) Inventors: Ting-Yu CHANG, Zhubei City (TW); Jian-Hsing LEE, Hsinchu City (TW); Yeh-Ning JOU, Hsinchu City (TW); Chih-Hsuan LIN, Hsinchu City (TW); Hsien-Feng LIAO, Taichung City (TW)

(73) Assignee: Vanguard International Semiconductor Corporation, Hsinchu (TW)

(21) Appl. No.: 19/058,779

(22) Filed: Feb. 20, 2025

(51) Int. Cl. H10D 89/60

(52) U.S. Cl. CPC H10D 89/713

(57) ABSTRACT

An electrostatic discharge structure including a first region, a first ring-shaped structure, a second ring-shaped structure, and a third ring-shaped structure is provided. The first ring-shaped structure surrounds the first region and includes a second region and a third region. The second ring-shaped structure surrounds the first ring-shaped structure and includes a fourth region and a fifth region. The third ring-shaped structure surrounds the second ring-shaped structure. The distance between the second and fourth regions is different from the distance between the third and fifth regions.

### BACKGROUND OF THE INVENTION

### Field of the Invention

The present invention relates to an electrostatic discharge (ESD) structure, and, in particular, it relates to an ESD structure that comprises multiple ESD elements.

### Description of the Related Art

As the process of manufacturing semiconductors has developed, electrostatic discharge (ESD) protection has become one of the most critical reliability issues for integrated circuits (IC). In particular, as semiconductor processing advances into the deep sub-micron stage, scaled-down devices and thinner gate oxides are more vulnerable to ESD stress. Generally, the input-output pads on IC chips are required to sustain at least 2 kVolt ESD stress of high Human Body Mode (HBM) or 200 Volts of Machine Mode. Thus, the input-output pads on IC chips are usually designed to include ESD protection devices or circuits for protecting the core circuits in IC chips from ESD damage.

### BRIEF SUMMARY OF THE INVENTION

In accordance with an embodiment of the disclosure, an electrostatic discharge structure comprises a first region, a first ring-shaped structure, a second ring-shaped structure, and a third ring-shaped structure. The first ring-shaped structure surrounds the first region and comprises a second region and a third region. The second ring-shaped structure surrounds the first ring-shaped structure and comprises a fourth region and a fifth region. The third ring-shaped structure surrounds the second ring-shaped structure. The distance between the second and fourth regions is different from the distance between the third and fifth regions.

### BRIEF DESCRIPTION OF THE DRAWINGS

The present invention can be more fully understood by reading the subsequent detailed description and examples with references made to the accompanying drawings, wherein:

FIG. 1 is a schematic diagram of an exemplary embodiment of an electrostatic discharge structure according to various aspects of the present disclosure.

FIG. 2A is a schematic diagram of another exemplary embodiment of the electrostatic discharge structure according to various aspects of the present disclosure.

FIG. 2B is a schematic diagram of the regional arrangement of the electrostatic discharge structure according to various aspects of the present disclosure.

FIG. 2C is a schematic diagram of the electrical contact terminals of the electrostatic discharge structure according to various aspects of the present disclosure.

FIG. 3A illustrates a cross-sectional view of the structure shown in FIG. 2B, wherein the cross-sectional view is obtained from the plane containing A-A′ in FIG. 2B.

FIG. 3B illustrates a cross-sectional view of the structure shown in FIG. 2B, wherein the cross-sectional view is obtained from the plane containing B-B′ in FIG. 2B.

FIG. 4A is a schematic diagram of the types of a first electrostatic discharge element in FIG. 3A.

FIG. 4B is a schematic diagram of the types of a second electrostatic discharge element in FIG. 3B.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

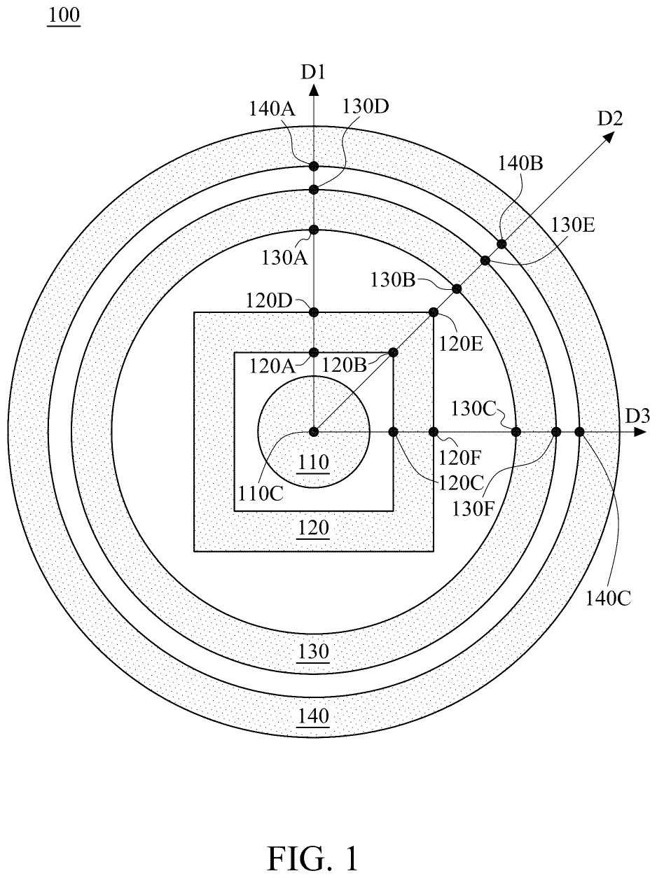

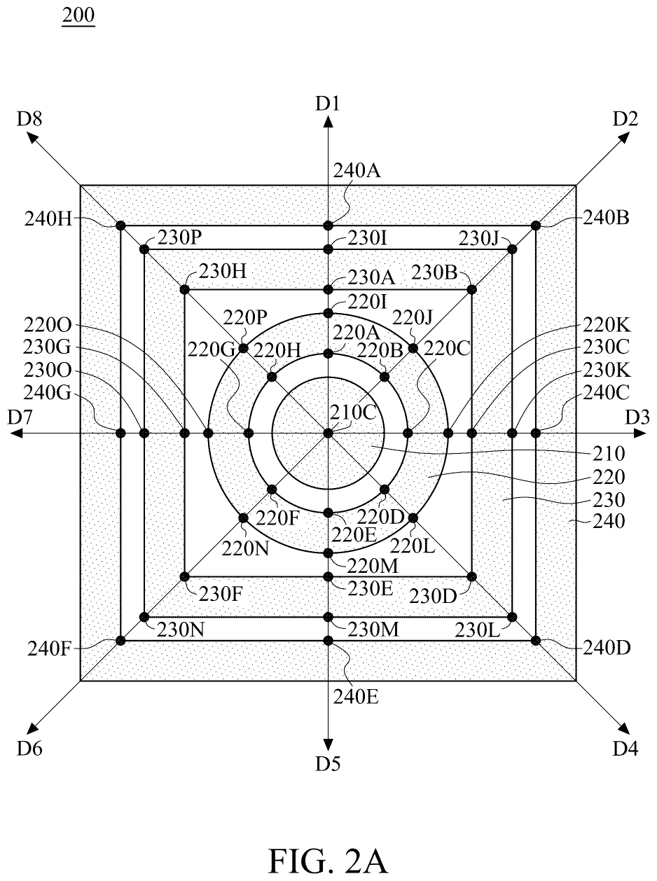

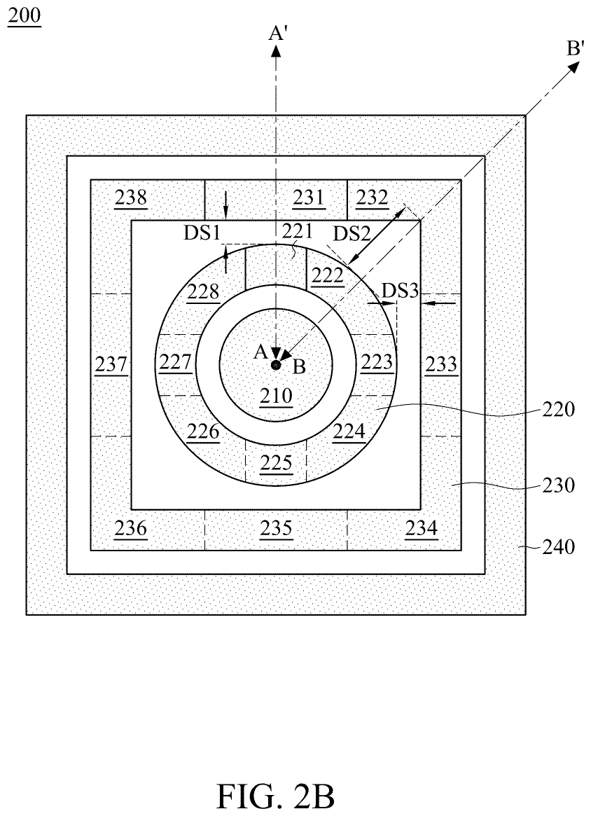

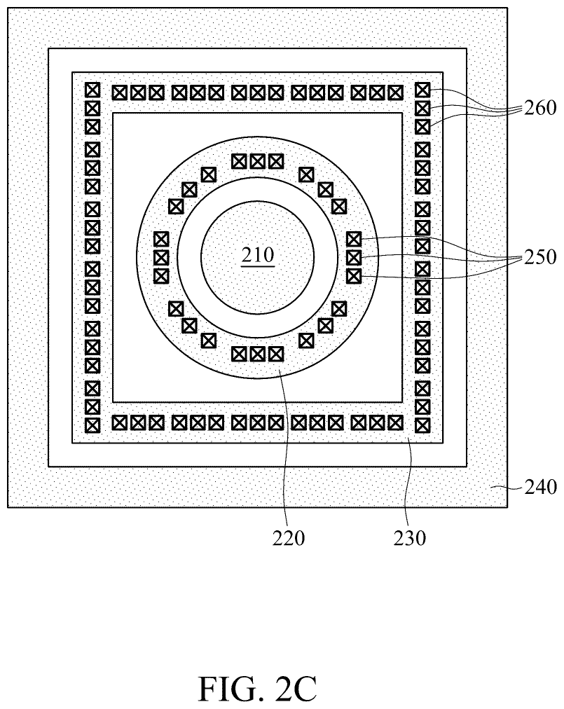

FIG. 1 is a schematic diagram of an exemplary embodiment of an electrostatic discharge structure according to various aspects of the present disclosure. As shown in FIG. 1, the electrostatic discharge (ESD) structure 100 comprises a region 110, ring-shaped structures 120, 130, and 140. The ring-shaped structure 120 surrounds the region 110. The shapes of the region 110 and ring-shaped structure 120 are not limited in the present disclosure. In this embodiment, the region 110 takes the form of a circle, and the ring structure 120 takes the form of a square. In other embodiments, the shape of the region 110 is the same as the shape of the electrostatic discharge structure 120. For example, the shapes of each of the region 110 and the ring-shaped structure 120 are rectangular circular (as shown in FIG. 2A).

The distance between the outside of the region 110 and the inside of the ring-shaped structure 120 it not limited in the present disclosure. In this embodiment, the distance between the center point 110C of the region 110 and a first point of the inside of the ring-shaped structure 120 is not equal to the distance between the center point 110C and a second point of the inside of the ring-shaped structure 120. Additionally, the distance between the center point 110C and the first point of the inside of the ring-shaped structure 120 may be equal to or may not be equal to the distance between the center point 110C and a third point of the inside of the ring-shaped structure 120.

For example, assume that the center point 110C extends in the directions D1 to D3 respectively, and intersects with the inside of the ring-shaped structure 120 at the points 120A, 120B, and 120C. In this case, the distance between the center point 110C and the point 120A is different from the distance between the center point 110C and the point 120B. Additionally, the distance between the center point 110C and the point 120A may be the same as or different from the distance between the center point 110C and the point 120C. In some embodiments, when the ring-shaped structure 120 is circular, the distance between the center point 110C and each point of the inside of the ring-shaped structure 120 is the same.

The ring-shaped structure 130 surrounds the ring-shaped structure 120. In this embodiment, the distance between a first point of the outside of the ring-shaped structure 120 and a first point of the inside of the ring-shaped structure 130 is different the distance between a second point of the outside of the ring-shaped structure 120 and a second point of the inside of the ring-shaped structure 130. In this case, the distance between the first point of the outside of the ring-shaped structure 120 and the first point of the inside of the ring-shaped structure 130 may be the same as or different from the distance between a third point of the outside of the ring-shaped structure 120 and a third point of the inside of the ring-shaped structure 130.

For example, the center point 110C extends in the direction D1 and intersects with the outside of the ring-shaped structure 120 at the point 120D and the inside of the ring-shaped structure 130 at the point 130A. Furthermore, the center point 110C extends in the direction D2 and intersects with the outside of the ring-shaped structure 120 at the point 120E and the inside of the ring-shaped structure 130 at the point 130B. In this case, the distance between the points 120D and 130A is different from the distance between the points 120E and 130B.

In another embodiment, the center point 110C extends in the direction D3 and intersects with the outside of the ring-shaped structure 120 at the point 120F and the inside of the ring-shaped structure 130 at the point 130C. In this case, the distance between the points 120F and 130C may be the same as or different from the distance between the points 120D and 130A.

The shape of the ring-shaped structure 130 is not limited in the present disclosure. In this embodiment, the shape of the ring-shaped structure 130 is circular. In other embodiments, the ring-shaped structures 120 and 130 are of a variety of other shapes, as long as the distance between a point of the outside of the ring-shaped structure 120 and a point of the inside of the ring-shaped structure 130 is different from the distance between another point of the outside of the ring-shaped structure 120 and another point of the inside of the ring-shaped structure 130.

The ring-shaped structure 140 surrounds the ring-shaped structure 130. In this embodiment, the shape of the ring-shaped structure 140 is the same as the shape of the ring-shaped structure 130, but the disclosure is not limited thereto. In other embodiments, the shape of the ring-shaped structure 140 is different from the shape of the ring-shaped structure 130.

In one embodiment, the distance between the outside of the ring-shaped structure 130 and the inside of the ring-shaped structure 140 is fixed. For example, the center point 110C extends in the direction D1 and intersects with the outside of the ring-shaped structure 130 at the point 130D and the inside of the ring-shaped structure 140 at the point 140A. The center point 110C extends in the direction D2 and intersects with the outside of the ring-shaped structure 130 at the point 130E and the inside of the ring-shaped structure 140 at the point 140B. In this embodiment, the distance between the points 130D and 140A is equal to the distance between the points 130E and 140B. Furthermore, the center point 110C extends in the direction D3 and intersects with the outside of the ring-shaped structure 130 at the point 130F and the inside of the ring-shaped structure 140 at the point 140C. In this case, the distance between the points 130F and 140C is equal to the distance between the points 130D and 140A and the distance between the points 130E and 140B.

In other embodiment, the distance a point in the outside of the ring-shaped structure 130 and a point in the inside of the ring-shaped structure 140 may be different from the distance between another point in the outside of the ring-shaped structure 130 and another point in the inside of the ring-shaped structure 140. Furthermore, the angle between directions D1 to D3 is not limited in the present disclosure. In one embodiment, the angle between directions D1 and D2 is 45 degrees, and the angle between directions D2 and D3 is 45 degrees.

FIG. 2A is a schematic diagram of another exemplary embodiment of the ESD structure according to various aspects of the present disclosure. The ESD structure 200 comprises a region 210, and ring-shaped structures 220, 230, and 240. FIG. 2A is similar to FIG. 1 with the exception that the shapes of the region 210 and the ring-shaped structure 220 are circular and the shapes of the ring-shaped structures 230 and 240 are rectangular.

In this embodiment, the center point 210C of the region 210 extends in the directions D1~D8 and intersects with the inside of the ring-shaped structure 220 at the points 220A~220H, respectively. In this case, the distances between the center point 210C and the points 220A~220H are fixed. Furthermore, the center point 210C extends in the directions D1~D8 and intersects with the outside of the ring-shaped structure 220 at the points 220I~220P, respectively. The center point 210C extends in the directions D1~D8 and intersects with the inside of the ring-shaped structure 230 at the points 230A~230H, respectively. In this case, the distance between the points 220I and 230A is different from the distance between the points 220J and 230B.

In some embodiments, the distance between the points 220I and 230A is the same as the distance between the points 220K and 230C, the distance between the points 220M and 230E, and the distance between the points 220O and 230G. In addition, the distance between the points 220J and 230B may be equal to the distance between the points 220L and 230D, the distance between the points 220N and 230F, and the distance between the points 220P and 230H.

The center point 210C extends in the directions D1~D8 and intersects with the outside of the ring-shaped structure 230 at the points 230I~230P, respectively. Furthermore, the center point 210C extends in the directions D1~D8 and intersects with the inside of the ring-shaped structure 240 at the points 240A~240H, respectively. In this embodiment, the distance between the points 230I and 240A is the same as the distance between the points 230J and 240B, the distance between the points 230K and 240C, the distance between the points 230L and 240D, the distance between the points 230M and 240E, the distance between the points 230N and 240F, the distance between the points 230O and 240G, and the distance between the points 230P and 230H.

FIG. 2B is a schematic diagram of the regional arrangement of the ESD structure according to various aspects of the present disclosure. In this embodiment, the ring-shaped structure 220 comprises regions 221 and 222. The conductivity type of the region 221 may be the same as or different from the conductivity type of the region 222. The number of regions is not limited in the present disclosure. The ring-shaped structure 220 may comprise the more regions, such as 223~228, but the disclosure is not limited thereto. In other embodiment, the ring-shaped structure 220 comprises any suitable number of regions.

The regions 221~228 are arranged in sequence to form the ring-shaped structure 220. In this case, each of regions 221~228 is adjacent to two regions and contacts the neighbor regions. For example, the region 222 is disposed between the regions 221 and 223 and contacts the regions 221 and 223. In one embodiment, the conductivity types of the regions 221, 223, 225, and 227 are the same, and the conductivity types of the regions 222, 224, 226, and 228 are the same.

Furthermore, the ring-shaped structure 230 comprises regions 231 and 232. The conductivity type of the region 231 may be the same as or different from the conductivity type of the region 232. Additionally, the conductivity type of the region 231 may be the same as or different from the conductivity type of the region 221, and the conductivity type of the region 232 may be the same as or different from the conductivity type of the region 222. In some embodiment, the ring-shaped structure 230 comprises the more regions, such as 233~238, but the disclosure is not limited thereto

The regions 231~238 are arranged in sequence to form the ring-shaped structure 230. In this case, each of regions 231~238 is adjacent to two regions and contacts the neighbor regions. For example, the region 232 is disposed between the regions 231 and 233 and contacts the regions 231 and 233. Additionally, the regions 231~238 correspond to the regions 221~228, respectively. In one embodiment, the conductivity types of the regions 231, 233, 235, and 237 are the same, and the conductivity types of the regions 232, 234, 236, and 238 are the same.

In some embodiments, the regions 210, 221, and 231 constitute a first ESD element, and the regions 210, 222 and 232 constitute a second ESD element. The type of first ESD element may be the same as or different from the type of second ESD element. In one embodiment, at least one of the first and second ESD elements is a PNP-type bipolar junction transistor (BJT), a NPN-type BJT, or a silicon controlled rectifier (SCR).

In other embodiments, the regions 210, 223, and 233 constitute a third ESD element, the regions 210, 224, and 234 constitute a fourth ESD element, the regions 210, 225, and 235 constitute a fifth ESD element, the regions 210, 226, and 236 constitute a sixth ESD element, the regions 210, 227, and 237 constitute a seventh ESD element, and the regions 210, 228, and 238 constitute an eighth ESD element. The type of one of the first to eighth ESD elements may be the same as or different from the type of another of the first to eighth ESD elements. In one embodiment, the first, third, fifth, and seventh ESD elements are the same type of ESD elements. In this case, the type of the first ESD element may be different from the type of the second ESD element.

FIG. 2C is a schematic diagram of the electrical contact terminals of the electrostatic discharge structure according to various aspects of the present disclosure. The ESD structure 200 further comprises a plurality of electrical contact terminals 250 and a plurality of electrical contact terminals 260. The electrical contact terminals 250 are evenly arranged in the ring-shaped structure 220. The ring-shaped structure 220 is electrically connected to a first input-output pad (not shown) via the electrical contact terminals 250. The electrical contact terminals 260 are evenly arranged in the ring-shaped structure 230. The ring-shaped structure 230 is electrically connected to a second input-output pad (not shown) via the electrical contact terminals 260. In some embodiments, the first input-output pad may be electrically connected to the second input-output pad.

In other embodiment, the region 210 comprises a plurality of electrical contact terminals (not shown), and the ring-shaped structure 240 also comprises a plurality of electrical contact terminals (not shown). In this case, the region 210 is electrically connected to a third input-output pad via the corresponding electrical contact terminals, and the ring-shaped structure 240 is electrically connected to a fourth input-output pad via the corresponding electrical contact terminals. When there is no ESD event, the first and second input-output pads receive a first operation voltage, the third input-output pad receives a second operation voltage, and the fourth input-output pad receives a third operation voltage. In some embodiment, the first operation voltage is less than the second operation voltage, and the third operation voltage may be equal to or less than the first operation voltage.

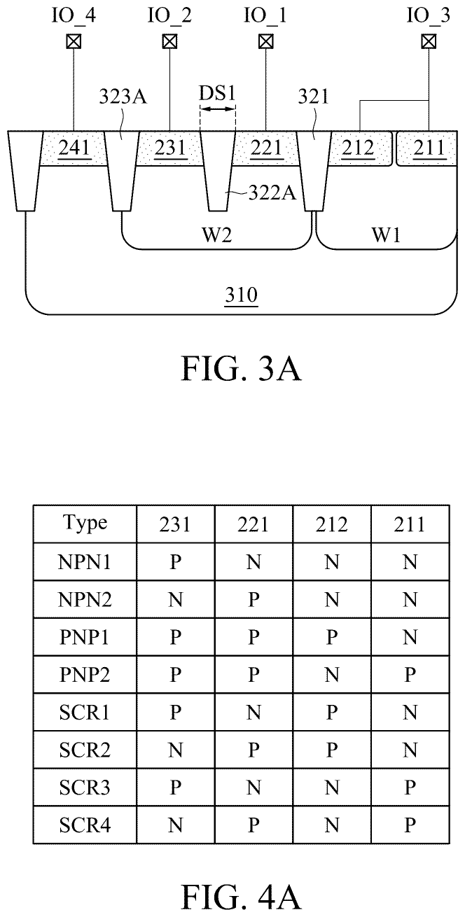

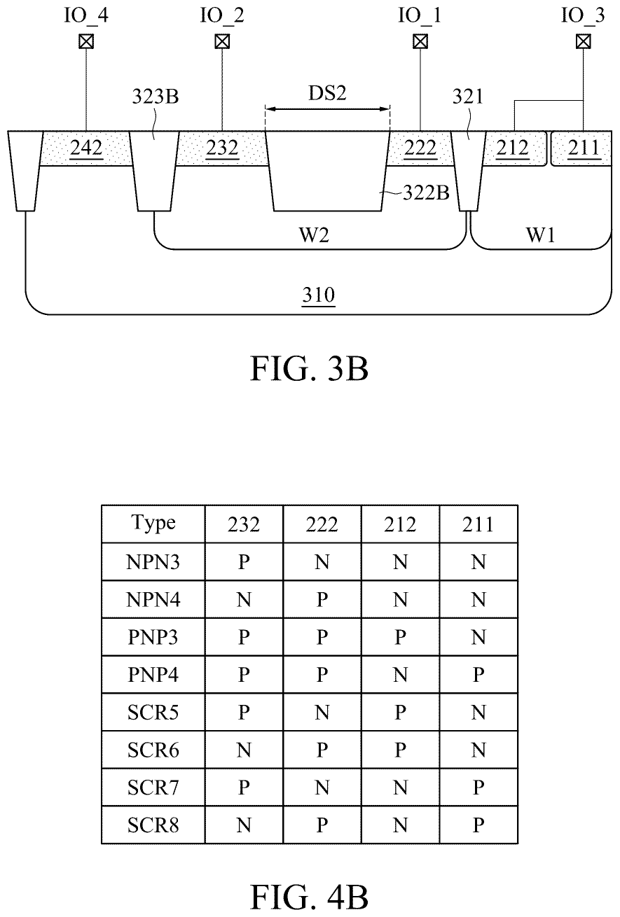

FIG. 3A illustrates a cross-sectional view of the structure shown in FIG. 2B, wherein the cross-sectional view is obtained from the plane containing A-A′ in FIG. 2B. The region 210 comprises doped regions 211 and 212. The conductivity type of the doped region 211 may be the same as or different from the conductivity type of the doped region 212. When the conductivity type of the doped region 211 is the same as the conductivity type of the doped region 212, the doped regions 211 and 212 may be integrated into a single doped region. When the conductivity type of the doped region 211 is different from the conductivity type of the doped region 212, the doped region 211 may contact the doped region 212. In another embodiment, when the conductivity type of the doped region 211 is different from the conductivity type of the doped region 212, there is an isolation structure (not shown) disposed between the doped regions 211 and 212. The isolation structure is spaced apart the doped region 211 from the doped region 212. In some embodiments, the doped region 212 is a ring-shaped structure (not shown) surrounding the doped region 211.

In other embodiments, the doped regions 211 and 212 are disposed in the well W1. The well W1 has a first conductivity type. In this case, when the conductivity type of the doped region 211 or 212 is the same as the conductivity type of the well W1, the doped concentration of the doped region 211 or 212 is higher than the doped concentration of the well W1. In some embodiments, the doped regions 211 and 212 are electrically connected to an input-output pad IO_3 via at least one electrical contact terminal (not shown).

The conductivity type of the region 221 may be the same as or different from the conductivity type of the region 231. In this embodiment, an isolation structure 322A is disposed between the regions 221 and 231. The isolation structure 322A has a width DS1 and is spaced apart the region 221 from the region 231. In one embodiment, the regions 221 and 231 are disposed in the well W2. The well W2 has a second conductivity type. The second conductivity type is different from the first conductivity type. For example, the second conductivity type is P type, and the first conductivity type is N type. In another embodiment, the second conductivity type is N type, and the first conductivity type is P type. In some embodiments, when the conductivity type of the region 221 or 231 is the same as the conductivity type of the well W2, the doped concentration of the region 221 or 231 is higher than the doped concentration of the well W2.

In other embodiments, the region 221 is electrically connected to an input-output pad IO_1 via at least one electrical contact terminal (not shown), and the region 231 is electrically connected to an input-output pad IO_2 via at least one electrical contact terminal (not shown). In one embodiment, the input-output pad IO_1 is electrically connected to the input-output pad IO_2.

The region 241 is a portion of the ring-shaped structure 240 and has the second conductivity type. The doped concentration of the region 241 is higher than the doped concentration of the well W2. In one embodiment, the region 241 is disposed in the substrate 310 and serves as the electrical contact terminal of the substrate 310. In this embodiment, the substrate 310 has the second conductivity type. The doped concentration of the substrate 310 is less than the doped concentration of the well W2. In some embodiment, the wells W1 and W2 are disposed in the substrate 310.

In other embodiments, the ESD structure 200 further comprises isolation structures 321 and 323A. The isolation structure 321 isolates the doped region 212 from the region 221. The isolation structure 323A isolates the region 231 from the region 241. In this embodiment, the doped regions 211 and 212, and the regions 221 and 231 constitute a first ESD element. FIG. 4A is a schematic diagram of the types of the first ESD in FIG. 3A.

In one embodiment, the conductivity types of the doped regions 211 and 212 are N type. In this case, when the conductivity type of the region 221 is different from the conductivity type of the region 231, the doped regions 211 and 212, and the regions 221 and 231 constitute a NPN-type BJT. For example, when the conductivity type of the region 221 is N type and the conductivity type of the region 231 is P type, the doped regions 211 and 212, and the regions 221 and 231 constitute a BJT NPN1. At this time, the doped regions 211 and 212, and the well W1 serve as the collector of the BJT NPN1. The well W2 and the region 231 serve as the base of the BJT NPN1. The region 221 serves as the emitter of the BJT NPN1. When the conductivity type of the region 221 is P type and the conductivity type of the region 231 is N type, the doped regions 211 and 212, and the regions 221 and 231 constitute a BJT NPN2. At this time, the doped regions 211 and 212, and the well W1 serve as the collector of the BJT NPN2. The well W2 and the region 221 serve as the base of the BJT NPN2. The region 231 serves as the emitter of the BJT NPN2.

In another embodiment, the conductivity types of the regions 221 and 231 are P type. In this case, when the conductivity type of the doped region 211 is different from the conductivity type of the doped region 212, the doped regions 211 and 212, and the regions 221 and 231 constitute a PNP-type BJT. For example, when the conductivity type of the doped region 211 is N type and the conductivity type of the doped region 212 is P type, the doped regions 211 and 212, and the regions 221 and 231 constitute a BJT PNP1. At this time, the doped region 212 serves as the emitter of the BJT PNP1. The doped region 211 and the well W1 serve as the base of the BJT PNP1. The regions 221 and 231, and the well W2 serve as the collector of the BJT PNP1. However, when the conductivity type of the doped region 211 is P type and the conductivity type of the doped region 212 is N type, the doped regions 211 and 212, and the regions 221 and 231 constitute a BJT PNP2. In this case, the doped region 211 and the well W1 serve as the base of the BJT PNP2. The doped region 212 serves as the emitter of the BJT PNP2. The regions 221 and 231, and the well W2 serve as the collector of the BJT PNP2.

In other embodiments, when the conductivity type of the doped region 211 is different from the conductivity type of the doped region 212 and the conductivity type of the region 221 is different from the conductivity type of the region 231, the doped regions 211 and 212, and the regions 221 and 231 constitute a silicon controlled rectifier. For example, the conductivity types of the doped region 211 and the region 221 are N type, and the conductivity types of the doped region 212 and the region 231 are P type. In this case, since the doped regions 212 and 211, the wells W1 and W2, and the regions 231 and 221 constitute a PNPN structure, the doped regions 212 and 211, and the regions 231 and 221 constitute a silicon controlled rectifier SCR1.

When the conductivity types of the doped region 211 and the region 231 are N type, and the conductivity types of the doped region 212 and the region 221 are P type, the doped regions 212 and 211, the wells W1 and W2, and the regions 221 and 231 constitute a PNPN structure. Therefore, the doped regions 212 and 211, and the regions 221 and 231 constitute a silicon controlled rectifier SCR2.

When the conductivity types of the doped region 211 and the region 231 are P type, and the conductivity types of the doped region 212 and the region 221 are N type, the doped regions 211 and 212, the wells W1 and W2, and the regions 231 and 221 constitute a PNPN structure. Therefore, the doped regions 211 and 212, and the regions 231 and 221 constitute a silicon controlled rectifier SCR3.

When the conductivity types of the doped region 211 and the region 221 are P type, and the conductivity types of the doped region 212 and the region 231 are N type, the doped regions 211 and 212, the wells W1 and W2, and the regions 221 and 231 constitute a PNPN structure. Therefore, the doped regions 211 and 212, and the regions 221 and 231 constitute a silicon controlled rectifier SCR4.

FIG. 3B illustrates a cross-sectional view of the structure shown in FIG. 2B, wherein the cross-sectional view is obtained from the plane containing B-B′ in FIG. 2B. FIG. 3B is similar to FIG. 3A with the exception that the width DS2 of the isolation structure 322B between the regions 222 and 232 is higher than the width DS1 of the isolation structure 322A between the regions 221 and 231 shown in FIG. 3A. In one embodiment, the projection area of the isolation structure 322B on the substrate 310 is larger than the projection area of the isolation structure 322A on the substrate 310.

The isolation structure 322B is disposed in the well W2 and isolates the region 222 from the region 223. In other embodiments, the region 222 is electrically connected to the input-output pad IO_1 via at least one electrical contact terminal (not shown). The region 232 is electrically connected to the input-output pad IO_2 via at least one electrical contact terminal (not shown). The conductivity type of the region 222 may be the same as or different from the conductivity type of the region 232. Taking the region 222 as an example, when the conductivity type of the region 222 is the same as the conductivity type of the well W2, the doped concentration of the region 222 is higher than the doped concentration of the well W2. When the conductivity type of the region 222 is the same as the conductivity type of the well W1, the doped concentration of the region 222 is higher than the doped concentration of the well W1. Additionally, the region 242 shown in FIG. 3B is a portion of the ring-shaped structure 240. Since the characteristic of the region 242 shown in FIG. 3B is similar to the characteristic of the region 241 shown in FIG. 3A, the related description is omitted here.

In this embodiment, the doped regions 211 and 212, and the regions 222 and 232 constitute a second ESD element. FIG. 4B is a schematic diagram of the types of the second ESD element in FIG. 3B. In one embodiment, the conductivity type of the doped regions 211 and 212 are N type. In this case, when the conductivity type of the region 222 is N type and the conductivity type of the region 232 is P type, the doped regions 211 and 212, and the regions 222 and 232 constitute a NPN-type BJT. In this case, the doped regions 211 and 212, and the well W1 serve as the collector of the BJT NPN3. The well W2 and the region 232 serve as the base of the BJT NPN3. The region 222 serves as the emitter of the BJT NPN3. However, when the conductivity type of the region 222 is P type and the conductivity type of the region 232 is N type, the doped regions 211 and 212, and the regions 222 and 232 constitute a NPN-type BJT. At this time, the doped regions 211 and 212, and the well W1 serve as the collector of a BJT NPN4. The well W2 and the region 222 serve as the base of the BJT NPN4. The region 232 serves as the emitter of the BJT NPN4.

In another embodiment, the conductivity types of the regions 222 and 232 are P type, and the conductivity type of the doped region 211 is different from the conductivity type of the doped region 212. In this case, when the conductivity type of the doped region 211 is N type and the conductivity type of the doped region 212 is P type, the doped regions 211 and 212, and the regions 222 and 232 constitute a PNP-type BJT. At this time, the doped region 211 and the well W1 serve as the base of a BJT PNP3. The doped region 212 serves as the emitter of the BJT PNP3. The regions 222 and 232, and the well W2 serve as the collector of the BJT PNP3. When the conductivity type of the doped region 211 is P type and the conductivity type of the doped region 212 is N type, the doped regions 211 and 212, and the regions 222 and 232 constitute a PNP-type BJT. At this time, the doped region 211 serves as the emitter of a BJT PNP4. The doped region 212 and the well W1 serves as the base of the BJT PNP4. The regions 222 and 232, and the well W2 serve as the collector of the BJT PNP4.

In other embodiments, when the conductivity type of the doped region 211 is different from the conductivity type of the doped region 212 and the conductivity type of the region 222 is different from the conductivity type of the region 232, the doped regions 211 and 212, and the regions 222 and 232 constitute a silicon controlled rectifier. For example, the conductivity types of the doped region 211 and the region 222 are N type, and the conductivity types of the doped region 212 and the region 232 are P type. In this case, since the doped regions 212 and 211, the wells W1 and W2, and the regions 232 and 222 constitute a PNPN structure, the doped regions 212 and 211, and the regions 232 and 222 constitute a silicon controlled rectifier SCR5.

When the conductivity types of the doped region 211 and the region 232 are N type, and the conductivity types of the doped region 212 and the region 222 are P type, the doped regions 212 and 211, the wells W1 and W2, and the regions 222 and 232 constitute a PNPN structure. Therefore, the doped regions 212 and 211, and the regions 222 and 232 constitute a silicon controlled rectifier SCR6.

When the conductivity types of the doped region 211 and the region 232 are P type, and the conductivity types of the doped region 212 and the region 222 are N type, the doped regions 211 and 212, the wells W1 and W2, and the regions 232 and 222 constitute a PNPN structure. Therefore, the doped regions 211 and 212, and the regions 232 and 222 constitute a silicon controlled rectifier SCR7.

When the conductivity types of the doped region 211 and the region 222 are P type, and the conductivity types of the doped region 212 and the region 232 are N type, the doped regions 211 and 212, the wells W1 and W2, and the regions 222 and 232 constitute a PNPN structure. Therefore, the doped regions 211 and 212, and the regions 222 and 232 constitute a silicon controlled rectifier SCR8.

Refer to FIG. 2B, assume that the regions 210 (including the doped region s 211 and 212), 221, and 231 constitute a first ESD element, and the regions 210, 222, and 232 constitute a second ESD element, In this case, since the width DS1 between the regions 221 and 231 is less than the width DS2 between the regions 222 and 232, the turn-on resistance of the first ESD element is less than the turn-on resistance of the second ESD element. Therefore, when an ESD event occurs in the region 210 and the ring-shaped structures 220 and 230 are coupled to ground, the second ESD element is first turned on. Then, the first ESD element is turned on.

In another embodiment, the regions 210, 223, and 233 constitute a third ESD element. In this case, since the width DS3 between the regions 223 and 233 is less than the width DS2 between the regions 222 and 232, the turn-on resistance of the third ESD element is less than the turn-on resistance of the second ESD element. Therefore, when an ESD event occurs in the region 210 and the ring-shaped structures 220 and 230 are coupled to ground, the second ESD element is first turned on. Then, the third ESD element is turned on. In some embodiments, when the width DS3 is larger than the width DS1, the third ESD element is turned on and then the first ESD element is turned on. However, when the width DS3 is less than the width DS1, the first ESD element is turned on earlier than the third ESD element.

In this embodiment, the distance (i.e., DS1~DS3) between the outside of the ring-shaped structure 220 and the inside of the ring-shaped structure 230 is related to the turn-on resistance of the ESD element. With increase of distance between the outside of the ring-shaped structure 220 and the inside of the ring-shaped structure 230, the turn-on resistance of the corresponding ESD element is increased. With decrease of distance between the outside of the ring-shaped structure 220 and the inside of the ring-shaped structure 230, the turn-on resistance of the corresponding ESD element is decreased. In response to the occurrence of an ESD event, an ESD element with a high turn-on resistance is turned on earlier than an ESD element with a low turn-on resistance.

In some embodiments, the first and second ESD elements may be BJTs. In this case, since the first and second ESD elements do not have snapback breakdown, it can be avoided that the first and second ESD elements are turned on under normal operation (no ESD event). In another embodiment, the first and second ESD elements may be SCRs. In this case, since the turn-on resistances of the first and second ESD elements are low, when an ESD event occurs, the first and second ESD elements can quickly discharge the ESD current.

In other embodiments, one of the first and second ESD elements is a BJT and the other is a SCR. In this case, when an ESD event occurs, the ESD element with the high turn-on resistance is first turned on, and then the ESD element with the low turn-on resistance is turned on. Since the SCR is turned on later than the BJT, the holding voltage of the SCR can be increased to prevent the SCR from being triggered under normal operation. Additionally, when an ESD event occurs, the SCR is turned on to quickly discharge the ESD current.

Refer to FIG. 2B, by controlling the conductivity types of the regions 221~228 and 231~238, the ESD structure 200 may have eight ESD elements. For example, the regions 210, 221, and 231 constitute a first ESD element. The regions 210, 222, and 232 constitute a second ESD element. The regions 210, 223, and 233 constitute a third ESD element. In other embodiments, when the ring-shaped structures 220 and 230 have other numbers of regions, the ESD structure 200 has other numbers of ESD elements. Furthermore, by controlling the conductivity types of the regions 221~228 of the ring-shaped structure 220 and the conductivity types of the regions 231~238 of the ring-shaped structure 230, the ESD 200 has other types of ESD elements.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge (ESD) structure, comprising:
a first region;
a first ring-shaped structure surrounding the first region and comprising a second region and a third region;
a second ring-shaped structure surrounding the first ring-shaped structure and comprising a fourth region and a fifth region; and
a third ring-shaped structure surrounding the second ring-shaped structure,
wherein a distance between the second and fourth regions is different from a distance between the third and fifth regions.

2. The ESD structure as claimed in claim 1, wherein the shape of the first ring-shaped structure is different from the shape of the second ring-shaped structure.

3. The ESD structure as claimed in claim 2, wherein the shape of the second ring-shaped structure is the same as the shape of the third ring-shaped structure.

4. The ESD structure as claimed in claim 2, wherein a conductivity type of the second region is different from a conductivity type of the fourth region, and the conductivity type of the first region is N type.

5. The ESD structure as claimed in claim 4, wherein the first, second, and fourth regions constitute a first transistor.

6. The ESD structure as claimed in claim 2, wherein the first region comprises a first doped region and a second doped region, the conductivity type of the first doped region is different from the conductivity type of the second doped region, and the conductivity type of the second region is the same as the conductivity type of the fourth region.

7. The ESD structure as claimed in claim 6, wherein the second doped region surrounds the first doped region.

8. The ESD structure as claimed in claim 6, wherein the first, second, and fourth regions constitute a second transistor.

9. The ESD structure as claimed in claim 8, wherein the conductivity type of the third region is different from the conductivity type of the fifth region.

10. The ESD structure as claimed in claim 9, wherein the first, third, and fifth regions constitute a silicon controlled rectifier (SCR).

11. The ESD structure as claimed in claim 10, further comprising:
a first input-output pad electrically connected to the first and second doped regions;
a second input-output pad electrically connected to the second and third ring-shaped structures; and
a third input-output pad electrically connected to the third ring-shaped structure.

12. The ESD structure as claimed in claim 11, further comprising:
a first isolation structure isolating the second region from the fourth region; and
a second isolation structure isolating the third region from the fifth region.

13. The ESD structure as claimed in claim 12, wherein in response to an occurrence of an ESD event, the SCR is turned on and then the second transistor is turned on.

14. The ESD structure as claimed in claim 12, further comprising:
a substrate;
a first well disposed in the substrate; and
a second well disposed in the substrate,
wherein the first and second doped regions are disposed in the first well, the first and second ring-shaped structures are disposed in the second well, and the third ring-shaped structure is disposed in the substrate.

15. The ESD structure as claimed in claim 14, wherein a projection area of the first isolation structure on the substrate is less than a projection area of the second isolation structure on the substrate.

16. The ESD structure as claimed in claim 14, wherein the conductivity type of the first well is different from the conductivity type of the second well, and the conductivity type of the second well is the same as the conductivity type of the substrate.

17. The ESD structure as claimed in claim 16, further comprising:
a third isolation structure disposed in the first well and isolating the first doped region from the second doped region.

18. The ESD structure as claimed in claim 1, wherein:
the first ring-shaped structure further comprises a sixth region and a seventh region,
the conductivity type of the sixth region is the same as the conductivity type of the second region, and the conductivity type of the seventh region is the same as the conductivity type of the third region,
the third region contacts the second and sixth regions, and
the sixth region contacts the third and seventh regions.

19. The ESD structure as claimed in claim 18, wherein:
the second ring-shaped structure further comprises an eighth region and a ninth region,
the conductivity type of the eighth region is the same as the conductivity type of the fourth region, and the conductivity type of the ninth region is the same as the conductivity type of the fifth region,
the fifth region contacts the fourth and eighth regions, and
the eighth region contacts the fifth and ninth regions.

20. The ESD structure as claimed in claim 19, wherein:
the first, second, and fourth regions constitute a first ESD element, the first, third and fifth regions constitute a second ESD element, the first, sixth and eighth regions constitute a third ESD element, and the first, seventh and ninth regions constitute a fourth ESD element,
in response to the first ESD element turning on, the third ESD element is turned on, and
in response to the second ESD element turning on, the fourth ESD element is turned on.
